(19) United States
(12) Patent Application Publication
(10) Pub. No.: US 2020/0098575 A1
(43) Pub. Date: Mar. 26, 2020

(54) Etching Method, Etching Apparatus, and Storage Medium

(71) Applicant: TOKYO ELECTRON LIMITED, Tokyo (JP)

(72) Inventors: Nobuhiro TAKAHASHI, Nirasaki City (JP); Yasuo ASADA, Nirasaki City (JP)

(21) Appl. No.: 16/578,795

(22) Filed: Sep. 23, 2019

(30) Foreign Application Priority Data
Sep. 25, 2018 (JP) 2018-178271

(51) Int. Cl. H01L 21/302; H01L 21/02; H01L 21/285

(52) U.S. Cl. CPC H01L 21/302; H01L 21/02312; H01L 21/28556; H01L 21/02381

(57) ABSTRACT

An etching method includes: preparing a substrate having SiGe or Ge and Si on a surface portion of the substrate; and selectively etching the SiGe or Ge with respect to the Si by supplying a process gas including a fluorine-containing gas and a hydrogen-containing gas to the substrate.

### CROSS-REFERENCE TO RELATED APPLICATION

This application is based upon and claims the benefit of priority from Japanese Patent Application No. 2018-178271, filed on Sep. 25, 2018, the entire contents of which are incorporated herein by reference.

### TECHNICAL FIELD

The present disclosure relates to an etching method, an etching apparatus, and a storage medium.

### BACKGROUND

In a semiconductor device manufacturing process of recent years, a side etching process is performed on a semiconductor wafer, in which a silicon germanium (SiGe) layer and a silicon (Si) layer are stacked, so as to selectively etch the silicon germanium layer with respect to the silicon layer. As a method of selectively etching the SiGe layer with respect to the Si layer, an etching process using a fluorine-containing gas such as ClF₃ gas, for example, as described in Patent Documents 1 and 2 is known. Such an etching process may be similarly applied to a selective etching process of a germanium (Ge) layer in a semiconductor wafer, in which the Ge layer and a Si layer coexist.

### PRIOR ART DOCUMENTS

### Patent Documents

Patent Document 1: Japanese laid-open publication No. 2009-510750

Patent Document 2: Japanese laid-open publication No. H1-92385

### SUMMARY

An aspect of the present disclosure provides an etching method including: preparing a substrate having SiGe or Ge and Si on a surface portion of the substrate; and selectively etching the SiGe or Ge with respect to the Si by supplying a process gas including a fluorine-containing gas and a hydrogen-containing gas to the substrate.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart for explaining an etching method according to an embodiment.

FIG. 2 is a sectional view illustrating a structural example of a wafer to which the etching method of the embodiment is applied.

FIG. 3 is a sectional view illustrating a state of the wafer having the structure of FIG. 2, where SiGe films are partially etched.

FIG. 4 is a sectional view illustrating a state of the wafer having the structure of FIG. 2, where the SiGe films are completely etched.

FIG. 5 is a view for explaining a structure of a sample for use in investigating a cause of damage to a Si film.

FIG. 6 is a view illustrating a reaction diagram when a reaction process of a GeF₄ gas and Si is simulated.

FIG. 7 is a view illustrating a reaction diagram when a reaction process of a SiF₄ gas and Si is simulated.

FIG. 8 is a schematic view illustrating a state of a wafer having a stacked structure of a SiGe film and Si films, where the SiGe film is etched using a ClF₃ gas.

FIG. 9 is a schematic view illustrating a state of a wafer having a stacked structure of a SiGe film and Si films, where the SiGe film is etched using a ClF₃ gas and a HF gas.

FIG. 10 is a view for explaining a surface state of a Si film in a wafer having a stacked structure of a SiGe film and the Si film, where the SiGe film is etched using a ClF₃ gas and a HF gas.

FIG. 11 is a schematic configuration view illustrating an example of a processing system for use in the etching method according to the embodiment.

FIG. 12 is a sectional view illustrating an etching apparatus for performing the etching method according to the embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, an embodiment will be described in detail with reference to the accompanying drawings.

### Background and Outline

First, the background and outline of an etching method according to an embodiment of the present disclosure will be described.

When SiGe and Si exist in a surface portion of a substrate, for example, when a stacked structure of SiGe and Si exists, a fluorine-containing gas such as a ClF₃ gas has been conventionally used for selectively etching the SiGe relative to the Si, as disclosed in Patent Documents 1 and 2.

However, it has been found that damage may occur to the Si when the fluorine-containing gas is used for etching the SiGe.

As a result of investigation on a reason for the cause of damage, it has been found that a GeF₄ gas is generated when etching the SiGe using the fluorine-containing gas, and the GeF₄ gas causes damage to the Si. This is also applicable to a case where Ge and Si exist in a surface portion of a substrate and the Ge is selectively etched with respect to the Si.

Therefore, in the embodiment, a substrate having SiGe or Ge and Si in a surface portion of the substrate is provided, and a fluorine-containing gas and a hydrogen-containing gas are supplied to the substrate to selectively etch the SiGe or Ge with respect to the Si.

By supplying the above-described gases, a SiH₄ gas, a GeH₄ gas, and the like are generated to reduce a concentration of a GeF₄ gas, and the Si is hydrogen-terminated. As a result, the SiGe or Ge is selectively etched with respect to the Si while suppressing damage to the Si.

### Embodiment of Etching Method

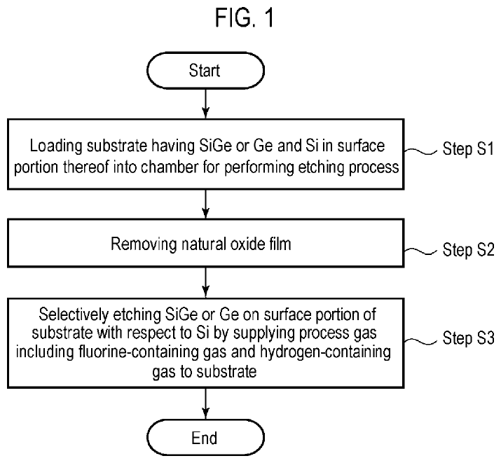

Next, a specific embodiment will be described. FIG. 1 is a flowchart illustrating an etching method according to an embodiment.

First, a substrate having SiGe or Ge and Si on a surface portion of the substrate is loaded into a chamber for performing an etching process (step S1).

A ratio of Si to Ge in the SiGe may be arbitrarily set, but Si may be 90 at % or less in some embodiments. Forms of the SiGe, Ge, and Si are not particularly limited, but those formed as films by a chemical vapor deposition (CVD) method are used as an example. The Si film may be doped with B, P, C, As, or the like. The substrate is not particularly limited, but a semiconductor wafer (hereinafter simply referred to as a “wafer”) is used as an example.

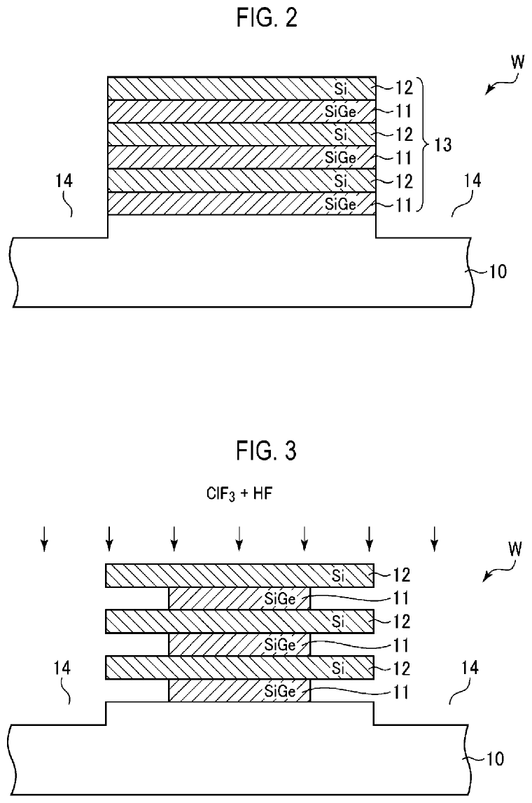

A structure of the substrate is also not particularly limited, but a wafer W having a structure, for example, as illustrated in FIG. 2 is used as an example. The wafer W of FIG. 2 has a stacked structure 13 in which SiGe films 11 and Si films 12 are alternately stacked on a surface of a semiconductor substrate 10 made of, for example, Si. Recesses 14 are formed in the stacked structure 13 by a plasma etching process, and side surfaces of the alternately stacked SiGe films 11 and Si films 12 are exposed in the recesses 14.

A natural oxide film is thinly formed on the surface of the substrate (stacked structure 13), and it is necessary to remove the natural oxide film. Therefore, after the substrate is loaded into the chamber, the natural oxide film is removed (step S2). The removal of the natural oxide film is performed, for example, by supplying a HF gas and a NH₃ gas. Alternatively, a natural oxide film removal process may be performed in another apparatus before the substrate is loaded into the chamber. In this case, a subsequent step S3 is performed just after the substrate is loaded into the chamber.

Next, a process gas including a fluorine-containing gas and a hydrogen-containing gas is supplied to the substrate to selectively etch the SiGe or Ge on the surface portion of the substrate with respect to the Si (step S3).

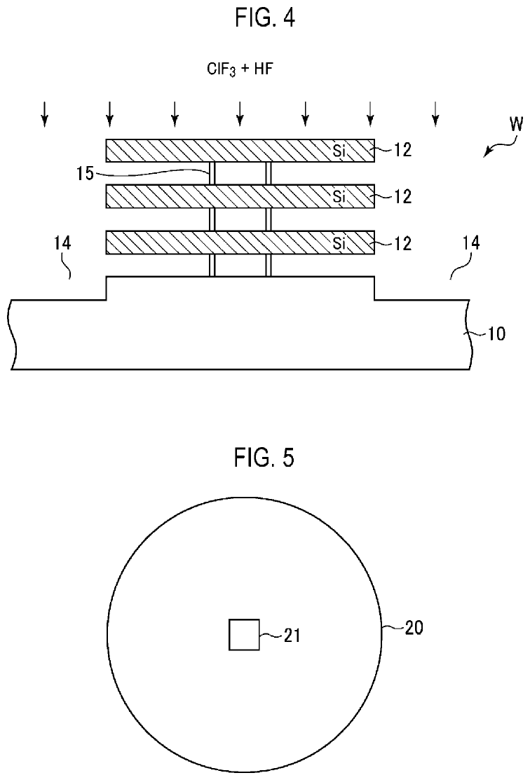

For example, by supplying a process gas including a fluorine-containing gas (e.g., a ClF₃ gas) and a hydrogen-containing gas (e.g., a HF gas) to the wafer W of FIG. 2, the SiGe films 11 are side-etched so that the SiGe films 11 are selectively etched with respect to the Si films 12 as illustrated in FIG. 3. In this case, the SiGe films 11 may be partially etched as illustrated in FIG. 3 or may be completely etched as illustrated in FIG. 4. Even if the SiGe films 11 are completely etched, the remaining Si films 12 are supported by a support columns 15 made of SiN or the like.

The fluorine-containing gas in the process gas functions as an etching gas. As the fluorine-containing gas, a ClF₃ gas, a F₂ gas, a SF₆ gas, an IF₇ gas or the like may be used. The hydrogen-containing gas in the process gas functions as a reaction gas which will described later. As the hydrogen-containing gas, a HF gas, a H₂ gas, a H₂S gas, or the like may be used. As the process gas, a rare gas such as an Ar gas or an inert gas such as N₂ gas may be supplied in addition to the fluorine-containing gas and the hydrogen-containing gas.

The reason for using the hydrogen-containing gas in addition to the fluorine-containing gas as the process gas as described above is as the following.

As disclosed in Patent Documents 1 and 2, a ClF₃ gas or the like has been conventionally used for selectively etching SiGe with respect to Si. This is because SiGe easily reacts with the fluorine-containing gas such as the ClF₃ gas, while Si hardly reacts with the ClF₃ gas.

However, it has been found that actually, when the wafer W illustrated in FIG. 2 is etched using the fluorine-containing gas such as ClF₃ gas, the Si films may be damaged.

Therefore, the reason for the cause of damage to the Si film was investigated.

First, samples as illustrated in FIG. 5, in each of which a chip 21 having the stacked structure of FIG. 2 was attached to a wafer 20 made of Si or SiGe, were prepared, and an etching process was performed using a ClF₃ gas. The temperature was set to 80 degrees C. As a result, in the case of the Si wafer, only the SiGe films in the chip 21 were etched and the Si films were hardly etched, whereas in the case of the SiGe wafer, the Si films in the chip 21 were significantly etched.

In the etching process using the fluorine-containing gas such as the ClF₃ gas, Si is hardly etched, but SiGe is etched and generates a SiF₄ gas and a GeF₄ gas. Therefore, it is considered that the Si films in the chip 21 on the SiGe wafer were etched by an act of the GeF₄ gas or the SiF₄ gas which were generated when the SiGe wafer was etched.

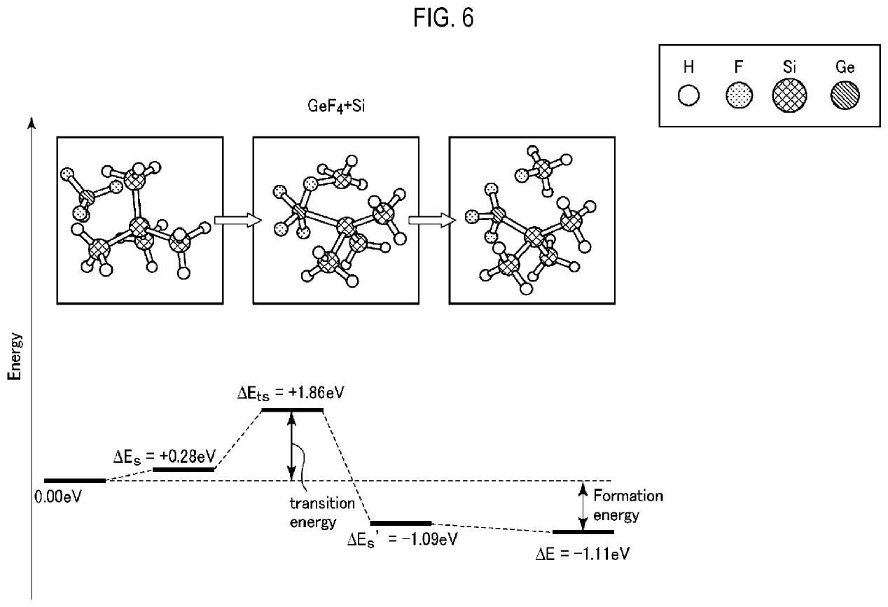

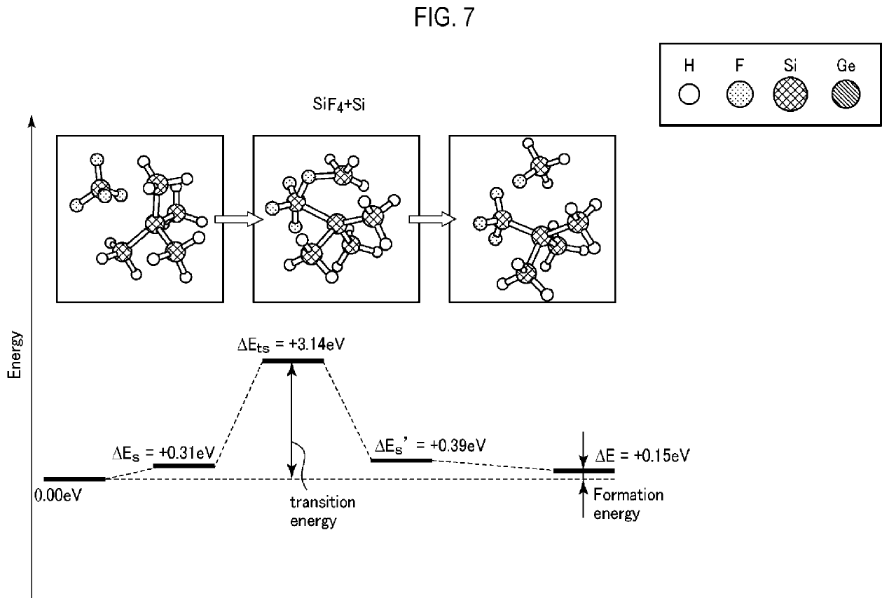

Next, a reaction process between a GeF₄ gas and Si and a reaction process between a SiF₄ gas and Si were simulated. FIGS. 6 and 7 illustrate reaction diagrams of the simulated reaction processes. In FIGS. 6 and 7, potential energy of each reaction step in the reaction processes was obtained given that the energy when the GeF₄ gas and the Si, and the SiF₄ gas and the Si exist independently is 0 eV. In this simulation, since the Si as an etching target is a Si film formed by CVD, hydrogen is contained in the film.

FIG. 6 represents the reaction process between the GeF₄ gas and the Si. Since the formation energy of a reactant has a negative value, it can be understood that the GeF₄ gas can react with the Si. FIG. 7 illustrates the reaction process between the SiF₄ gas and the Si. Since the formation energy of to reactant has a positive value, it can be understood that the SiF₄ gas cannot react with the Si.

From the foregoing, it was found that the damage occurring in the Si during the conventional etching process using the F-containing gas such as the ClF₃ gas is caused by the GeF₄ gas which is generated when the SiGe is etched.

A specific example is as the following.

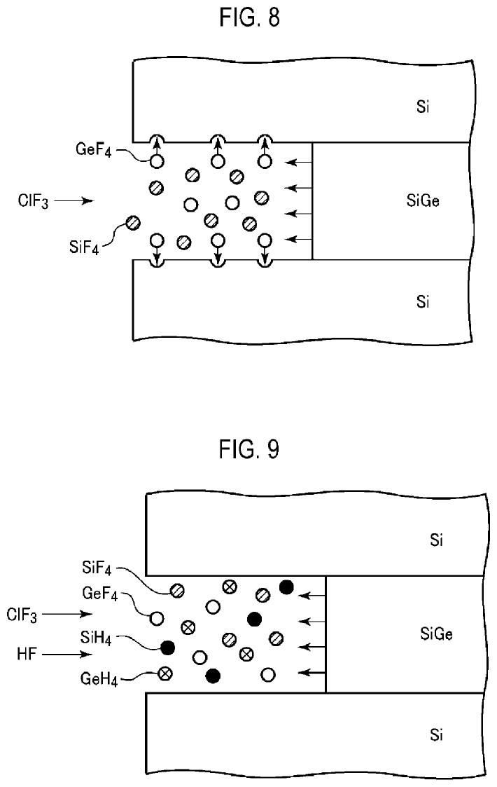

FIG. 8 is a schematic view illustrating a state of a wafer W having the stacked structure 13 of the SiGe films 11 and the Si films 12 as illustrated in FIG. 2, where the SiGe film 11 is etched by a ClF₃ gas. As illustrated in FIG. 8, the SiGe film 11 is etched by the ClF₃ gas, for example, according to Equation (1) as the following (in Equation (1), a valence is not considered and a Cl-containing product is not described).

SiGe+ClF₃→SiF₄+GeF₄ (1)

The Si film 12 is hardly etched by the ClF₃ gas. However, as illustrated in FIG. 8, the Si film 12 is damaged by GeF₄ generated according to Equation (1).

The GeF₄ gas is also generated when the SiGe is etched using other fluorine-containing gases such as a F₂ gas. Thus, the Si film 12 is similarly damaged.

In contrast, in the present embodiment, a hydrogen-containing gas such as a HF gas is used in addition to the conventionally used fluorine-containing gas. As a result, in addition to the generation of the SiF₄ gas and the GeF₄ gas by the fluorine-containing gas, the hydrogen-containing gas reacts with the SiGe and generates the GeH₄ gas and the SiH₄ gas. Thus, the concentration of the GeF₄ gas is reduced, which suppressed the Si from being damaged. In addition, the surface of the Si is H-terminated by the hydrogen-containing gas, which protects the Si from the GeF₄ gas. By the above-described two acts, it is possible to selectively etch the SiGe or Ge with respect to the Si while very effectively suppressing the Si from being damaged. Therefore, an etching selectivity of the SiGe or Ge to the Si is increased to be 100 or more, which results in a good etching profile of the Si.

A specific example is as the following.

FIG. 9 is a schematic view illustrating a state a wafer W having the stacked structure 13 of the SiGe films 11 and the Si films 12 as illustrated in FIG. 2, where the SiGe film 11 is etched by a ClF₃ gas and a HF gas. As illustrated in FIG. 9, the SiGe film 11 is etched by the ClF₃ gas and the HF gas, for example, according to Equation (2) as the following (in Equation (2), a valence is not considered and a Cl-containing product is not described).

SiGe+ClF₃+HF→SiF₄+GeF₄+SiH₄+GeH₄ (2)

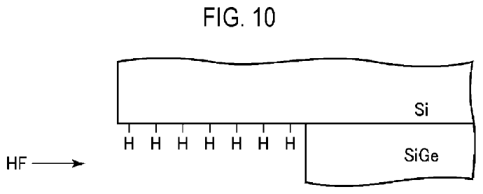

As described above, although the GeF₄ gas is generated, the concentration of the GeF₄ gas is reduced by the SiH₄ gas and the GeH₄ gas, which are generated by the HF gas. Thus, the amount of the GeF₄ gas reaching the Si films 12 is reduced, and the Si is suppressed from being damaged. In addition, as illustrated in FIG. 10, the surfaces of the Si films 12 are H-terminated by the hydrogen-containing gas, which protects the Si films 12 from the GeF₄ gas. By the above-described acts, it is possible to etch the SiGe film 11 while very effectively suppressing the Si films 12 from being damaged.

The above-described effect can be also obtained even when a gas other than the HF gas, such as a H₂ gas or a H₂S gas, is used as the hydrogen-containing gas.

In the etching process of step S3, a flow rate of the fluorine-containing gas may be in a range of 1 to 500 sccm, and a flow rate of the hydrogen-containing gas may be in a range of 50 to 1000 sccm. In the case of supplying an inert gas, a flow rate of the inert gas may be in a range of 100 to 1000 sccm. In some embodiments, a flow rate ratio F/H, which is a ratio of a flow rate (F) of the fluorine-containing gas to a flow rate (H) of the hydrogen-containing gas, may be set in a range of 0.001 to 10, from the viewpoint of advancing the etching process while effectively preventing the Si from being damaged.

A pressure in the chamber in the etching process of step S3 may be set in a range of 0.133 to 1,130 Pa (1 mTorr to 10 Torr), and in some embodiments, may be set in a range of 1.33 to 133 Pa (10 mTorr to 1 Torr). A process temperature (wafer temperature) may be set in a range of 0.1 to 150 degrees C., and in some embodiments, may be set in a range of 20 to 120 degrees C.

After the etching process of step S3, a residue removal process is performed as needed. The method of removing the residue is not particularly limited, but may be performed, for example, by a heat treatment.

### Example of Processing System

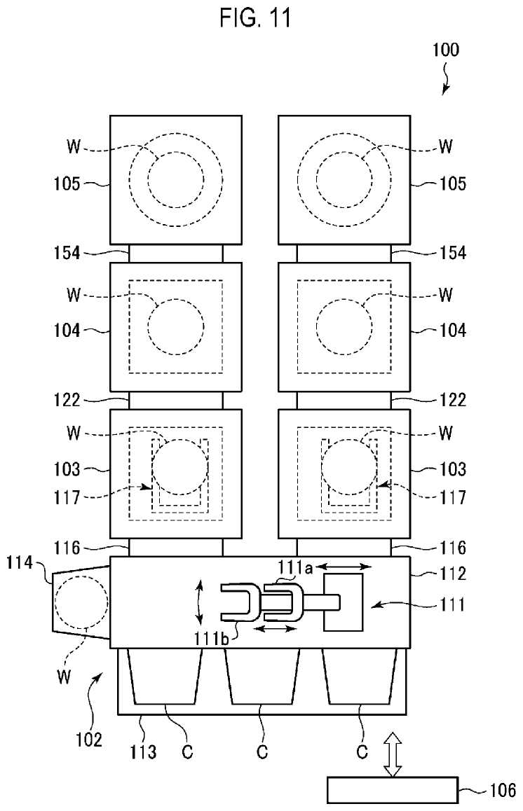

Next, an example of a processing system for use in the etching method according to the embodiment will be described. FIG. 11 is a schematic block diagram illustrating an example of the processing system.

As shown in FIG. 11, a processing system 100 includes: a loading and unloading part 102 through which wafers W, for example, having the structure illustrated in FIG. 2 are loaded and unloaded; two load-lock chambers 103 provided adjacent to the loading and unloading part 102;

heat treatment apparatuses 104, which are provided adjacent to the load-lock chambers 103, respectively, for performing heat treatment on the wafers W; etching apparatuses 105, which are provided adjacent to the heat treatment apparatuses 104, respectively, for performing an etching process on the wafers W; and a controller 106.

The loading and unloading part 102 has a transfer chamber 112 in which a first wafer transfer mechanism 111 for transferring a wafer W is provided. The first wafer transfer mechanism 111 has two transfer arms 111a and 111b for holding a wafer W substantially in a horizontal position. A stage 113 is provided beside a long side of the transfer chamber 112. For example, three carriers C, such as FOUPs, for storing a plurality of wafers W are connected to the stage 113. In addition, an alignment chamber 114 for aligning the wafer W is provided adjacent to the transfer chamber 112.

In the loading and unloading part 102, the wafer W is held by the transfer arm 111a or 111b, and is transferred to a desired position by linear movements in a substantially horizontal plane or upward and downward movements, which are driven by the first wafer transfer mechanism 111. The wafer W is also loaded and unloaded with respect to the carriers C on the stage 113, the alignment chamber 114, and the load-lock chambers 103, by advancing and retracting movements of the transfer arms 111a and 111b.

Each load-lock chamber 103 is connected to the transfer chamber 112 with a gate valve 116 interposed between the load-lock chamber 103 and the transfer chamber 112. A second wafer transfer mechanism 117 for transferring the wafer W is provided in each load-lock chamber 103. In addition, the load-lock chamber 103 can be vacuum-evacuated to a predetermined degree of vacuum.

The second wafer transfer mechanism 117 has an articulated arm structure, and has a pick for holding the wafer W substantially in a horizontal position. The second wafer transfer mechanism 117 is configured such that the pick is positioned in the load-lock chamber 103 when the articulated arm is contracted, the pick reaches the heat treatment apparatus 104 when the articulated arm is extended, and the pick reaches the etching apparatus 105 when the articulated arm is further extended. Thus, the wafer W can be transferred among the load-lock chamber 103, the heat treatment apparatus 104, and the etching apparatus 105.

The controller 106 is typically constituted with a computer, and includes a main controller having a CPU for controlling respective components of the processing system 100, an input device (e.g., a keyboard or a mouse), an output device (e.g., a printer), a display device (e.g., a display), and a storage device (a storage medium). The main controller of the controller 106 causes the processing system 100 to execute a predetermined operation based on, for example, a process recipe stored in, for example, a storage medium embedded in the storage device or a storage medium set in the storage device.

With the processing system 100, a plurality of wafers W on which the above-described structure is formed is stored in the carrier C, and is transferred to the processing system 100. With the processing system 100, a sheet of wafer W is transferred, in a state where the gate valve 116 at the atmospheric side is open, from the carrier C of the loading and unloading part 102 to the load-lock chamber 103 by one of the transfer arms 111a and 111b of the first wafer transfer mechanism 111, and is delivered to the pick of the second wafer transfer mechanism 117 in the load-lock chamber 103.

Thereafter, the gate valve 116 at the atmospheric side is closed to vacuum-evacuate the load-lock chamber 103. Subsequently, gate valves 122 and 154 are opened, and the pick is extended to the etching apparatus 105 to transfer the wafer W to the etching apparatus 105.

Thereafter, the pick is returned to the load-lock chamber 103, and the gate valve 154 is closed. Then, the etching process of the SiGe films is performed in the etching apparatus 105 by the etching method described above.

After the etching process is completed, the gate valves 122 and 154 are opened, and when necessary, the wafer W after the etching process is transferred to the heat treatment apparatus 104 by the pick of the second wafer transfer mechanism 117 to remove etching residues or the like by heat.

After the etching process is completed or after the heat treatment in the heat treatment apparatus 104 is completed after the etching process, the wafer W is returned to the carrier C by one of the transfer arms 111a and 111b of the first wafer transfer mechanism 111. Thus, processing of a sheet of wafer is completed.

When it is not necessary to remove the etching residues or the like, the heat treatment apparatus 104 may not be provided. In that case, the wafer W after the etching process may be retracted to the load-lock chamber 103 by the pick of the second wafer transfer mechanism 117, and may be returned to the carrier C by one of the transfer arms 111a and 111b of the first wafer transfer mechanism 111.

### Etching Apparatus

Next, an example of the etching apparatus 105 for carrying out the etching method according to the embodiment will be described in detail.

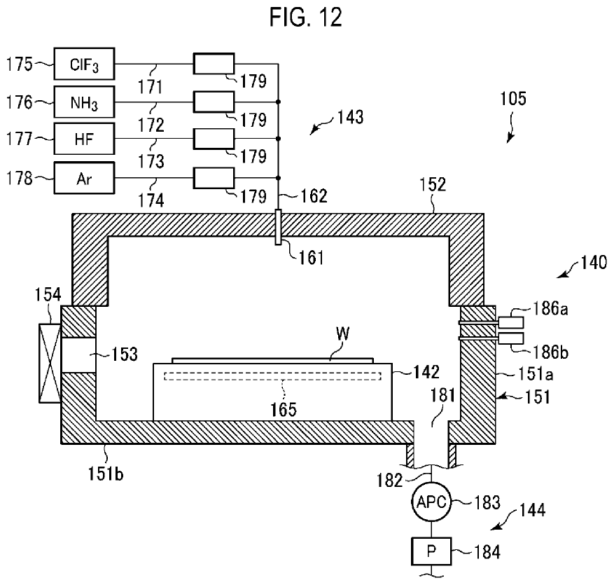

FIG. 12 is a sectional view illustrating an example of the etching apparatus 105. As illustrated in FIG. 12, the etching apparatus 105 includes a chamber 140 having a sealed structure as a process container that defines a process space. A stage 142 on which a wafer W is placed in a substantially horizontal position is provided in the chamber 140. The etching apparatus 105 further includes a gas supply 143 that supplies an etching gas to the chamber 140 and an exhauster 144 that exhausts the inside of the chamber 140.

The chamber 140 is constituted with a chamber main body 151 and a lid 152. The chamber main body 151 has a substantially cylindrical side wall portion 151a and a bottom portion 151b, and has an open top that is closed by the lid 152. The side wall portion 151a and the lid 152 are sealed by a sealing member (not illustrated) to ensure airtightness of the interior of the chamber 140. A gas inlet nozzle 161 is inserted from above into the ceiling wall of the lid 152 toward the interior of the chamber 140.

A loading and unloading port 153 for loading and unloading the wafer W with respect to the heat treatment apparatus 104 is provided at the side wall portion 151a. The loading and unloading port 153 is opened and closed by the gate valve 154.

The stage 142 has a substantially circular shape in a plan view, and is fixed to the bottom portion 151b of the chamber 140. A temperature adjuster 165 for adjusting a temperature of the stage 142 is embedded in the stage 142. The temperature adjuster 165 includes, for example, a pipeline in which a temperature adjustment medium (e.g., water) circulates. The temperature of the stage 142 is adjusted by heat exchange with the temperature adjustment medium flowing in the pipeline, whereby a temperature of the wafer W on the stage 142 is controlled.

The gas supply 143 includes a ClF₃ gas supply source 175 that supplies a ClF₃ gas as a fluorine-containing gas, an NH₃ gas supply source 176 that supplies a NH₃ gas, an HF gas supply source 177 that supplies a HF gas as a hydrogen-containing gas, and an Ar gas supply source 178 that supplies an Ar gas as an inert gas. One ends of pipes 171, 172, 173, and 174 are connected to the gas supply sources 175 to 178, respectively. The other ends of the pipes 171, 172, 173, and 174 are connected to a common pipe 162, and the common pipe 162 is connected to the gas inlet nozzle 161 described above.

Therefore, the ClF₃ gas as a fluorine-containing gas, the NH₃ gas, the HF gas as a hydrogen-containing gas, and the Ar gas as an inert gas reach the common pipe 162 via pipes 171, 172, 173, and 174 from the ClF₃ gas supply source 175, the NH₃ gas supply source 176, the HF gas supply source 177, and the Ar gas supply source 178, respectively, and are discharged from the gas inlet nozzle 161 toward the wafer W in the chamber 140.

Each of the pipes 171, 172, 173, and 174 is provided with a flow rate controller 179 configured to perform an opening and closing operation of a flow path and a flow rate control. The flow rate controller 179 is constituted with, for example, an opening and closing valve and a mass flow controller.

The etching apparatus 105 of this example is a pre-mix type apparatus in which a mixture of the ClF₃ gas and the HF gas is discharged to the chamber 140. However, the etching apparatus 105 may be a post-mix type apparatus in which the ClF₃ gas and the HF gas are separately discharged. In addition, a shower plate may be provided in an upper portion of the chamber 140, and the gases may be supplied in a shower shape through the shower plate. In order to achieve the post-mix of the gases using the shower plate, a matrix shower may be used in which the gases are not mixed in the shower.

Among the above-described gases, the ClF₃ gas as a fluorine-containing gas is an etching gas, and the HF gas as a hydrogen-containing gas is a reaction gas for suppressing the Si film from being damaged. The Ar gas as an inert gas is used as a dilution gas and a purge gas. The NH₃ gas is used for removing a natural oxide film.

The exhauster 144 includes an exhaust pipe 182 connected to an exhaust port 181 formed in the bottom portion 151b of the chamber 140, and further includes an automatic pressure control (APC) valve 183 provided in the exhaust pipe 182 so as to control the pressure of the interior of the chamber 140 and a vacuum pump 184 configured to evacuate the chamber 140.

At the side wall of the chamber 140, two capacitance manometers 186a and 186b, as pressure gauges for measuring the pressure in the chamber 140, are inserted into the chamber 140. The capacitance manometer 186a is for high pressure, and the capacitance manometer 186b is for low pressure. In the vicinity of the wafer W placed on the stage 142, a temperature sensor (not illustrated) is provided to detect the temperature of the wafer W.

Respective components of the etching apparatus 105 are controlled by the controller 106 of the processing system 100. The main controller of the controller 106 controls the respective components of the etching apparatus 105 such that the etching method described below is performed based on, for example, a processing recipe stored in a storage medium embedded in the storage device or a storage medium set in the storage device.

In the etching apparatus 105, a wafer W having the structure illustrated in FIG. 2, for example, is loaded into the chamber 140 and placed on the stage 142. The pressure in the chamber 140 may be set in a range of 0.133 to 1,330 Pa (1 mTorr to 10 Torr), and in some embodiments, may be set in a range of 1.33 to 133 Pa (10 mTorr to 1 Torr). In addition, the temperature of the wafer W may be set in a range of 0.1 to 150 degrees C., and some embodiments, may be set in a range of 20 to 120 degrees C. by the temperature adjuster 165 of the stage 142.

Then, when the natural oxide film removal process is performed in the chamber 140, the HF gas and the NH₃ gas, which are hydrogen-containing gases, are supplied to the chamber 140, and react with the natural oxide film to generate ammonium fluorosilicate. Thereafter, the ammonium fluorosilicate is sublimated by a heat treatment. Alternatively, a natural oxide film removal apparatus may be separately provided in the processing system 100, and the wafer W may be loaded into the chamber 140 after the natural oxide film is removed. In that case, it is not necessary to perform the natural oxide film removal process in the chamber 140.

Subsequently, the ClF₃ gas as the fluorine-containing gas is supplied to the chamber 140 at a flow rate of, for example, 1 to 10 sccm, and the HF gas as the hydrogen-containing gas is supplied to the chamber 140 at a flow rate of, for example, 100 to 500 sccm, so that the SiGe film is etched. At this time, the flow rate ratio F/H, which is the ratio of the flow rate (F) of the fluorine-containing gas to the flow rate (H) of the hydrogen-containing gas, may be set in the range of 0.001 to 0.1. In addition, when necessary, the inert gas such as the Ar gas may be supplied at a flow rate of, for example, 100 to 1000 sccm.

As described above, by using the ClF₃ gas as the fluorine-containing gas and the HF gas as the hydrogen-containing gas, it is possible to selectively etch the SiGe or Ge with respect to the Si while very effectively suppressing the Si from being damaged. Therefore, the etching selectivity of the SiGe or Ge to the Si is increased to be 100 or more, which results in a good etching profile of the Si.

### Experimental Examples

Subsequently, experimental examples will be described.

### Experimental Example 1

SiGe films in wafers having the structure illustrated in FIG. 2 were etched by supplying a F₂ gas as the fluorine-containing gas, a HF gas as the hydrogen-containing gas, and an Ar gas as the inert gas (Case 1). In addition, for comparison, SiGe films in wafers having the same structure were etched by supplying a F₂ gas and an Ar gas without supplying a HF gas (Case 2). The etching processes were performed using the etching apparatus having the structure as illustrated in FIG. 12. Conditions in the etching processes were as the following.

Case 1
Pressure: 6.6 to 66.6 Pa (50 to 500 mTorr)
Gas flow rate: F₂=30 to 100 sccm
   HF=40 to 150 sccm
   Ar=100 to 250 sccm
Flow rate ratio F₂/HF: 0.5 to 5
Wafer temperature: 20 to 120 degrees C.

Case 2
Pressure: 6.6 to 66.6 Pa (50 to 500 mTorr)
Gas flow rate: F₂=30 to 200 sccm
   Ar=100 to 500 sccm
Wafer temperature: 20 to 120 degrees C.

With respect to Cases 1 and 2, states of the wafers were inspected. As a result, in Case 1, the Si films were hardly etched, and the SiGe films were selectively etched. Thus, the etching selectivity of the SiGe films to the Si films was as high as 133.3, and the etching profile of the Si was also good. In contrast, in Case 2, surfaces of the Si films were damaged and became uneven. Therefore, it was impossible to calculate the etching selectivity. From this, it was confirmed that, by adding the HF gas to the F₂ gas, it is possible to etch the SiGe films at a high selectivity with respect to the Si films while effectively suppressing the surfaces of the Si films from being damaged.

### Experimental Example 2

SiGe films in wafers having the structure illustrated in FIG. 2 were etched by supplying a ClF₃ gas as the fluorine-containing gas, a HF gas as the hydrogen-containing gas, and an Ar gas as the inert gas (Case 3). In addition, for comparison, SiGe films in wafers having the same structure were etched by supplying a ClF₃ gas and an Ar gas without supplying a HF gas (Case 4). In addition, as in Experimental Example 1, the etching processes were performed using the etching apparatus having the structure as illustrated in FIG. 12. Conditions in the etching processes were as the following.

Case 3
Pressure: 6.6 to 66.6 Pa (50 to 500 mTorr)
Gas flow rate: ClF₃=1 to 50 sccm
   HF=100 to 500 sccm
   Ar=100 to 500 sccm
Flow rate ratio ClF₃/HF: 0.005 to 0.5
Wafer temperature: 20 to 120 degrees C.

Case 4
Pressure: 6.6 to 66.6 Pa (50 to 500 mTorr)
Gas flow rate: ClF₃=1 to 50 sccm
   Ar=300 to 1,000 sccm
Wafer temperature: 20 to 120 degrees C.

With respect to Cases 3 and 4, states of the wafers were inspected. As a result, in Case 3, the Si films were hardly etched, and the SiGe films were selectively etched. Thus, the etching selectivity of the SiGe films to the Si films was as high as 160.0, and the etching profile of the Si was also good. In contrast, in Case 4, the surfaces of Si films were damaged. Thus, although the etching selectivity of the SiGe films to the Si films were 109.1 exceeding 100, the end surface portions of the Si films were thin and thus the etching profile of the Si was bad. From this, it was confirmed that, by adding the HF gas to the ClF₃ gas, it is possible to etch the SiGe films at a high selectivity with respect to the Si films while effectively suppressing the surfaces of the Si films from being damaged.

### Other Applications

Although embodiments have been described above, it should be understood that the embodiments disclosed herein are illustrative and non-restrictive in all respects. The above embodiments may be omitted, replaced, or modified in various forms without departing from the scope and spirit of the appended claims.

For example, the structural example of the substrate shown in FIG. 2 is merely an example, and any substrate having SiGe or Ge and Si in the surface portion is applicable. In addition, the structures of the processing system and the etching apparatus are merely examples, and systems and apparatuses having various configurations may be used. Although the case in which a semiconductor wafer is used as a substrate has been described, the substrate may be another substrate such as a flat panel display (FPD) substrate represented by a liquid crystal display (LCD) substrate or a ceramic substrate without being limited to the semiconductor wafer.

According to the present disclosure, with respect to a substrate having SiGe or Ge and Si on a surface portion of the substrate, it is possible to selectively etch the SiGe or Ge while suppressing the Si from being damaged.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. An etching method comprising:
preparing a substrate having SiGe or Ge and Si on a surface portion of the substrate; and
selectively etching the SiGe or Ge with respect to the Si by supplying a process gas including a fluorine-containing gas and a hydrogen-containing gas to the substrate.

2. The etching method of claim 1, wherein the hydrogen-containing gas suppresses the Si from being damaged.

3. The etching method of claim 1, wherein the SiGe or Ge is a SiGe film or a Ge film, and the Si is a Si film.

4. The etching method of claim 3, wherein the SiGe film, the Ge film, and the Si film are formed by chemical vapor deposition.

5. The etching method of claim 3, wherein the substrate has a stacked structure on the surface portion of the substrate, the stacked structure being a structure in which the SiGe film and the Si film are alternately stacked.

6. The etching method of claim 1, wherein the fluorine-containing gas is selected from a group consisting of a ClF₃ gas, a F₂ gas, a SF₆ gas, and an IF_{S} gas.

7. The etching method of claim 1, wherein the hydrogen-containing gas is selected from a group consisting of a HF gas, a H₂ gas, and a H₂S gas.

8. The etching method of claim 1, wherein a ratio of a flow rate of the fluorine-containing gas to a flow rate of the hydrogen-containing gas is in a range of 0.001 to 10.

9. The etching method of claim 1, wherein a pressure in the selectively etching the SiGe or Ge is in a range of 0.133 to 1,330 Pa.

10. The etching method of claim 1, wherein a temperature of the substrate in the selectively etching the SiGe or Ge is in a range of 0.1 to 150 degrees C.

11. The etching method of claim 1, further comprising removing a natural oxide film on a surface of the substrate before the selectively etching the SiGe or Ge.

12. An etching apparatus comprising:
a chamber configured to accommodate a substrate having SiGe or Ge and Si on a surface portion of the substrate;
a stage configured to place the substrate on the stage in the chamber;
a gas supply configured to supply a process gas including a fluorine-containing gas and a hydrogen-containing gas to the chamber;
an exhauster configured to evacuate the interior of the chamber;
a temperature adjuster configured to adjust a temperature of the substrate placed on the stage; and
a controller,
wherein the controller is configured to control the gas supply, the exhauster, and the temperature adjuster such that the SiGe or Ge is selectively etched with respect to the Si.

13. A non-transitory computer-readable storage medium that stores a program executed on a computer to control an etching apparatus, wherein the program causes the computer to control the etching apparatus such that the etching method of claim 1 is performed.
